(19) United States
(12) Patent Application Publication
(10) Pub. No.: US 2020/0033425 A1
(43) Pub. Date: Jan. 30, 2020

(54) ENCAPSULATED MAGNETIC TUNNEL JUNCTION (MTJ) STRUCTURES

(71) Applicant: Globalfoundries Singapore Pte. Ltd., Singapore (SG)

(72) Inventors: Chenchen Jacob Wang, Singapore (SG); Taiebeh Tahmasebi, Singapore (SG); Ganesh Kolliyil Rajan, Singapore (SG); Dimitri Houssameddine, Singapore (SG); Michael Nicolas Albert Tran, Singapore (SG)

(21) Appl. No.: 16/044,616

(22) Filed: Jul. 25, 2018

(51) Int. Cl. G01R 33/09; G11C 11/16; H01L 43/02; H01L 27/22

(52) U.S. Cl. CPC G01R 33/098; G11C 11/161; B82Y 25/00; H01L 27/228; H01L 43/02

(57) ABSTRACT

Integrated circuits and methods for fabricating integrated circuits with magnetic tunnel junction (MTJ) structures are provided. An exemplary method for fabricating an integrated circuit includes forming a magnetic tunnel junction (MTJ) structure and conformally forming a metal oxide encapsulation layer over and around the MTJ structure. The method further includes removing a portion of the metal oxide encapsulation layer over MTJ structure. Also, the method includes forming a conductive via over and in electrical communication with the top surface of the MTJ structure.

### TECHNICAL FIELD

The technical field generally relates to integrated circuits, and more particularly relates to integrated circuits with magnetic tunnel junction structures encapsulated by metal oxide layers during processing.

### BACKGROUND

Magnetic (or magneto-resistive) random access memory (MRAM) is a non-volatile random access memory technology that could potentially replace the dynamic random access memory (DRAM) and flash memory as the standard memory for computing devices. The use of MRAM as a non-volatile RAM will eventually allow for “instant on” systems that come to life as soon as the system is turned on, thus saving the amount of time needed for a conventional PC, for example, to transfer boot data from a hard disk drive to volatile DRAM during system power up.

A magnetic memory element (also referred to as a tunneling magneto-resistive or TMR device) includes a structure having ferromagnetic layers separated by a non-magnetic layer (barrier), and arranged into a stacked magnetic tunnel junction (MTJ) structure. Digital information is stored and represented in the memory element as directions of magnetization vectors in the magnetic layers. More specifically, the magnetic moment of one magnetic layer (also referred to as a reference layer) is fixed or pinned, while the magnetic moment of the other magnetic layer (also referred to as a “free” layer) may be switched between the same direction and the opposite direction with respect to the fixed magnetization direction of the reference layer. The orientations of the magnetic moment of the free layer are also known as “parallel” and “antiparallel” states, wherein a parallel state refers to the same magnetic alignment of the free and reference layers, while an antiparallel state refers to opposing magnetic alignments therebetween.

In all of these ferromagnetic layer applications, there is the problem of preventing oxidation of the various metal layers during processing subsequent to the initial layer depositions and patterning. Often this problem is addressed by encapsulating the depositions with a thin layer of silicon nitride, which is an excellent oxidation preventative. Unfortunately, such a layer loses its integrity and/or becomes etched away during subsequent processing such as annealing processes at high temperatures or metal etching processes required for bit line patterning.

Accordingly, it is desirable to provide a method of fabricating integrated circuits in which ferromagnetic layers in MTJ structures are protected from oxidation with encapsulation layers that survive the rigors of subsequent processing. It is also desirable to provide integrated circuits with MTJ structures encapsulated by metal oxide layers. Further, it is desirable to provide a method for fabricating an integrated circuit with MTJ structures that is cost effective and time efficient. Furthermore, other desirable features and characteristics will become apparent from the subsequent detailed description and the appended claims, taken in conjunction with the accompanying drawings and this background.

### BRIEF SUMMARY

Integrated circuits and methods for fabricating integrated circuits with magnetic tunnel junction (MTJ) structures are provided. An exemplary method for fabricating an integrated circuit includes forming a magnetic tunnel junction (MTJ) structure and conformally forming a metal oxide encapsulation layer over and around the MTJ structure. The method further includes removing a portion of the metal oxide encapsulation layer over MTJ structure. Also, the method includes forming a conductive via over and in electrical communication with the top surface of the MTJ structure.

Another exemplary embodiment provides a method for encapsulating a magnetic tunnel junction (MTJ) structure. The method includes providing the magnetic tunnel junction (MTJ) structure including a top electrode layer, MTJ layers, and a bottom electrode layer. Further, the method includes forming a titanium oxide encapsulation layer over and around the MTJ structure. The method includes etching a portion of the titanium oxide encapsulation layer to expose a portion of MTJ structure. Also, the method includes forming a conductive via over and in electrical communication with the portion of the MTJ structure.

In yet another exemplary embodiment, an integrated circuit is provided. The integrated circuit includes a magnetic tunnel junction (MTJ) structure and a conductive via over and in electrical communication with a portion of the MTJ structure. Further, the integrated circuit includes a titanium oxide encapsulation layer surrounding the MTJ structure.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

The various embodiments will hereinafter be described in conjunction with the following drawing figures, wherein like numerals denote like elements, and wherein:

FIGS. 1-5 illustrate cross sectional views of a portion of an integrated circuit including a magnetic tunnel junction (MTJ) structure and a method of forming the same with an electrical connection to the MTJ structure according to various embodiments herein, specifically:

FIG. 1 illustrates formation of an MTJ structure in accordance with an embodiment herein;

FIG. 2 illustrates formation of a metal oxide encapsulation layer over the MTJ structure of FIG. 1 in accordance with an embodiment herein;

FIGS. 3-5 illustrate patterning of the metal oxide encapsulation layer and the formation of an electrical connection to the MTJ structure of FIG. 2 in accordance with various embodiments herein.

### DETAILED DESCRIPTION

The following detailed description is merely exemplary in nature and is not intended to limit the integrated circuits with magnetic tunnel junction structures or methods for fabricating integrated circuits with magnetic tunnel junction structures. Furthermore, there is no intention to be bound by any expressed or implied theory presented in the preceding technical field, background or brief summary, or in the following detailed description.

For the sake of brevity, conventional techniques related to conventional device fabrication may not be described in detail herein. Moreover, the various tasks and processes described herein may be incorporated into a more comprehensive procedure or process having additional functionality not described in detail herein. In particular, various techniques in semiconductor fabrication processes are well-known and so, in the interest of brevity, many conventional techniques will only be mentioned briefly herein or will be omitted entirely without providing the well-known process details. Further, it is noted that integrated circuits include a varying number of components and that single components shown in the illustrations may be representative of multiple components. As used herein, when a layer or structure is a recited material, that material is present in the layer or structure in an amount of at least 50 wt. % in relation to the total weight of the layer or structure unless otherwise indicated. As used herein, when a layer or structure is primarily a recited material, that material is present in the layer or structure in an amount of at least 90 wt. % in relation to the total weight of the layer or structure unless otherwise indicated.

The drawings are semi-diagrammatic and not to scale. Particularly, some of the dimensions are for the clarity of presentation and are shown exaggerated in the drawings. Similarly, although the views in the drawings for ease of description generally show similar orientations, this depiction in the drawings is arbitrary. Generally, the integrated circuit can be operated in any orientation. As used herein, it will be understood that when an element or layer is referred to as being “over” or “under” another element or layer, it may be directly on the other element or layer, or intervening elements or layers may be present. When an element or layer is referred to as being “on” another element or layer, it is directly on and in contact with the other element or layer. Further, spatially relative terms, such as “upper”, “over”, “lower”, “under” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as being “under” other elements or features would then be oriented “above” the other elements or features. Thus, the exemplary term “under” can encompass either an orientation of above or below. The device may be otherwise oriented (rotated 90 degrees or at other orientations) and the spatially relative descriptors used herein may likewise be interpreted accordingly. Further, as used herein, “encapsulating” refers to completely surrounding and covering an element with another material or materials.

In accordance with the various embodiments herein, integrated circuits including magnetic tunneling junction (MTJ) structures and methods for fabricating integrated circuits with MTJ structures are provided. Generally, the following embodiments relate to the encapsulation of an MTJ structure with an overlying metal oxide encapsulation layer. In an exemplary embodiment, the encapsulation layer is titanium oxide (TiO). During fabrication, the metal oxide layer protects the deposited and patterned ferromagnetic layers in the MTJ structure from oxidation through contact with oxygen. Further, the metal oxide layer resists degradation during subsequent processing, such as during metal etching processes required for bit line patterning or during annealing processes at high temperatures, such as higher than 350° C., higher than 400° C., or higher than 500° C. Also, it has been found that the metal oxide encapsulation layer may serve as a barrier to deuterium during a high pressure deuterium anneal (HPD2) process, which is required in some advanced semiconductor process after wafer fabrication process is done.

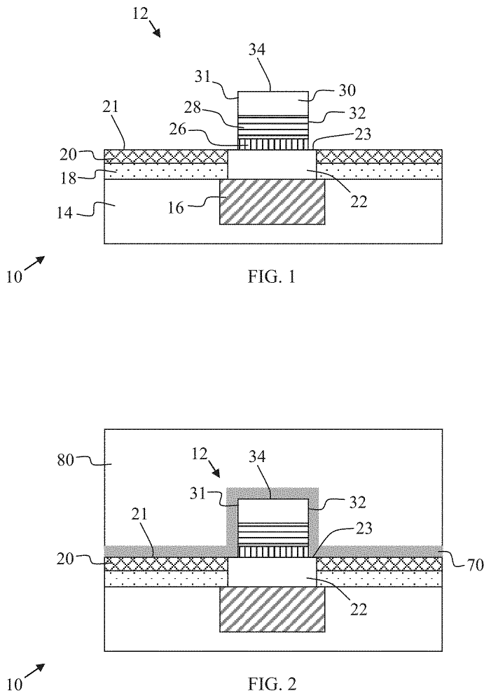

FIGS. 1-5 illustrate, in cross section, an integrated circuit 10 and methods for fabricating an integrated circuit 10 in accordance with embodiments of the present disclosure. Each of FIGS. 1-5 illustrates a memory portion of the integrated circuit 10, wherein a stacked MTJ structure 12 is to be formed. The integrated circuit 10 illustrated in FIG. 1 includes an inter-layer dielectric (ILD) layer 14 and a metallization layer 16 within the ILD layer 14. By the term “within,” it is meant that a top surface of the metallization layer 16 is substantially coplanar with a top surface of the ILD layer 14, and the metallization layer 16 extends downward into the ILD layer 14, as illustrated in FIG. 1.

The ILD layer 14 may be formed of one or more low-k dielectric materials such as, for example, un-doped silicate glass (USG), silicon nitride, silicon oxynitride, or other commonly used materials. The dielectric constants (k value) of the low-k dielectric materials may be less than about 3.9, for example, less than about 2.8. The metallization layer 16 may be formed of a metal, such as copper or copper alloys. In one particular, non-limiting embodiment, the metallization layer 16 is a third metallization layer (M3) or fourth metallization layer (M4). One skilled in the art will realize the formation details of the ILD layer 14 and the metallization layer 16.

Though not illustrated for simplicity in FIGS. 1-5, the ILD layer 14 and the metallization layer 16 may be formed over other ILD and/or metallization layers, and also over an active region of a semiconductor substrate forming part of the integrated circuit structure. As used herein, the term “semiconductor substrate” may include any semiconductor materials typically used in the formation of electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, and the like. The substrate may further include a plurality of isolation features (not shown), such as shallow trench isolation (STI) features or local oxidation of silicon (LOCOS) features. The isolation features may define and isolate the various microelectronic elements (not shown), also referred to herein as the aforesaid active regions. Examples of the various microelectronic elements that may be formed in the substrate include transistors (e.g., metal oxide semiconductor field effect transistors (MOSFET): bipolar junction transistors (BJT); resistors; diodes; capacitors; inductors; fuses; or other suitable elements. Various processes are performed to form the various microelectronic elements including deposition, etching, implantation, photolithography, annealing, or other suitable processes. The microelectronic elements are interconnected to form the integrated circuit device, such as a logic device, memory device, radio frequency (RF) device, input/output (I/O) device, system-on-chip (SoC) device, combinations thereof, or other suitable types of devices.

As further illustrated in FIG. 1, a passivation layer 18 is formed over the top surface of the metallization layer 16 and the ILD layer 14. The passivation layer 18 may be formed of a non-organic material selected from un-doped silicate glass (USG), silicon nitride, silicon oxynitride, silicon oxide, or combinations thereof. In some alternative embodiments, the passivation layer 18 is formed of a polymer material, such as an epoxy, polyimide, benzocyclobutene (BCB), polybenzoxazole (PBO), or the like, although other relatively soft, often organic, dielectric materials may also be used.

In a specific, non-limiting embodiment, the passivation layer 18 may be formed of a silicon carbide-based passivation material including nitrogen. In one example, silicon carbide with nitrogen deposited using chemical vapor deposition (CVD) from a trimethylsilane source, which is commercially available from Applied Materials under the tradename of BLOK®, is used as the passivation layer 18. The compound with less nitrogen (N) (less than about 5 mol %), i.e., SiₐC_{b}N_{c}H_{d}, is referred to as “BLoK”, and the compound with more N (about 10 mol % to about 25 mol %), i.e., Si_{w}CₓN_{y}H_{z}, is referred to as “NBLoK”. BLoK has a lower dielectric constant of less than 4.0, whereas NBLoK has a dielectric constant of about 5.0. While BLoK is not a good oxygen barrier but is a good copper (Cu) barrier, NBLoK is both a good oxygen barrier and a good Cu barrier. In an exemplary embodiment, the passivation layer 18 is or includes NBLoK material.

In FIG. 1, a dielectric layer 20 is formed over the passivation layer 18. An exemplary dielectric layer 20 is silicon oxide, though other suitable dielectric materials may be used. In an exemplary embodiment, the dielectric layer 20 is formed by a deposition process utilizing tetraethyl orthosilicate (TEOS). Further, as shown, the passivation layer 18 and dielectric layer 20 are patterned to form an opening directly over the metallization layer 16. For example, a photoresist material layer (not shown) may be deposited over the dielectric layer 20 and patterned by exposure to a light source using known photolithographic processes. The patterning is performed so as to remove the photoresist material layer in an area directly over the metallization layer 16 and expose an upper surface of the dielectric layer 20 in the area that is directly over metallization layer 16. One or more etching processes are then performed to transfer the pattern into the dielectric layer 20 and passivation layer 18, forming a trench therein in the area that is directly over the metallization layer 16. As a result of the one or more etching processes, all or a portion of the upper surface of the metallization layer 16 is exposed. The remaining portions of the patterned photoresist layer are then removed (for example by a suitable polishing or planarization process), resulting substantially in the structure of passivation layer 18 and dielectric layer 20 illustrated in FIG. 1 (before formation of overlying layers), wherein the remaining portions (non-etched) of the upper surface of the dielectric layer 20 are exposed, along with at least a portion of the upper surface of the metallization layer 16.

As shown in FIG. 1, after the illustrated structure of the passivation layer 18 and dielectric layer 20 is formed, a conductive contact layer 22 is formed on the upper surface of the metallization layer 16. An exemplary contact layer 22 is embedded in the dielectric layer 20. An exemplary contact layer 22 is a conductive material, such as a metal or a metal alloy. As used herein, the term “metal” broadly refers to the following elements:
Group 2 or IIA metals including beryllium (Be), magnesium (Mg), calcium (Ca), strontium (Sr), barium (Ba), and radium (Ra);
Groups 3-12 including transition metals (Groups MB, IVB, VB, VIB, VIIB, VIII, IB, and IIB), including scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), and mercury (Hg);
Group 13 or IIIA including boron (B), aluminum (Al), gallium (Ga), indium (In), and thallium (TI): Lanthanides including lanthanum (La), cerium (Ce), praseodymium (Pr), neodymium (Nd), promethium (Pm), samarium (Sm), europium (Eu), gadolinium (Gd), terbium (Th), dysprosium (Dy), holmium (Ho), erbium (Er), thulium (Tm), ytterbium (Yb), and lutetium (Lu);
Group 14 or IVA including germanium (Ge), tin (Sn), and lead (Pb); and
Group 15 or VA including antimony (Sn) and bismuth (Bi).

In an embodiment, contact layer 22 is tantalum, tantalum nitride or tungsten. In an exemplary embodiment, the conductive material is deposited by chemical vapor deposition (CVD) on to the metallization layer 16 and is planarized, such as by chemical mechanical planarization (CMP) to form an upper surface 21 of the dielectric layer 20 coplanar with an upper surface 23 of the contact layer 22.

Then, a bottom electrode layer 26 is formed over the dielectric layer 20 and contact layer 22. An exemplary bottom electrode layer 26 is a conductive material, such as a metal or a metal alloy as described above. In an exemplary embodiment, bottom electrode layer 26 is tantalum, tantalum nitride, titanium, tungsten, and/or other commonly used conductive metals. In an exemplary embodiment, the bottom electrode layer 26 is formed by depositing the conductive material by a CVD process.

The method may continue by forming MTJ layers (collectively illustrated and identified by reference number 28) over the bottom electrode layer 26. For example, MTJ materials may be successively blanket deposited over the upper surface of the contact layer 22 and dielectric layer 20. In an exemplary embodiment, the MTJ layers 28 include a pinning layer, fixed magnetic layer, tunnel barrier layer, and free magnetic layer, spacer/capping layer, as well as optional seed layers, wetting layers, spacer layers, anti-ferromagnetic layers, and the like. It is realized that the MTJ structure 12 may include MTJ layers 28 of many variations that are within the scope of the present disclosure.

FIG. 1 further illustrates that the MTJ structure 12 includes a top electrode layer 30. Top electrode layer 30 is a conductive material, such as a metal or a metal alloy, as described above. In an exemplary embodiment, top electrode layer 30 is tantalum, tantalum nitride, titanium, tungsten, and/or other commonly used conductive metals. In an exemplary embodiment, the top electrode layer 30 is formed by depositing the conductive material by a CVD process.

As shown, bottom electrode layer 26, MTJ layers 28, and top electrode layer 30 are etched to form the MTJ structure 12 with sidewalls 31 and 32. For example, a photoresist material layer (not shown) may be deposited and patterned over the top electrode layer 30, in the manner previously described with regard to the photoresist material layer used to etch the dielectric layer 20 and passivation layer 18, using a pattern that leaves a mask segment of photoresist material disposed over the area that is directly over the metallization layer 16. The photoresist segment serves as an etch mask for an etching process. The etching may be performed on the basis of a known technique, such as for example using tetrafluoromethane (CF₄) reactive ion etching (RIE) or hydrogen bromide (HBr). As a result of etching, portions of the bottom electrode layer 26, MTJ layers 28, and top electrode layer 30 over the dielectric layer 20 and over outer portions of the contact layer 22 are removed. The portion of the bottom electrode layer 26, MTJ layers 28, and top electrode layer 30 directly underneath the photoresist material mask segment are not etched. Upon subsequent removal of the photoresist mask segment, the bottom electrode layer 26, MTJ layers 28, and top electrode layer 30 form the MTJ structure 12 and have sidewalls 31 and 32. As shown, the MTJ structure 12 has a top surface 34 formed by the top electrode layer 30.

In FIG. 2, the structure of the partially fabricated integrated circuit 10 is shown. Further to the process described in relation to FIG. 1 above, FIG. 2 illustrates the deposition of an encapsulation layer 70. In an exemplary embodiment, the encapsulation layer 70 is conformally deposited, such as by a physical vapor (PVD) process. The encapsulation layer 70 may be conformally deposited by sputtering. An exemplary encapsulation layer 70 is metal oxide, such as titanium oxide or tantalum oxide. Further, an exemplary encapsulation layer 70 is primarily metal oxide, such as primarily titanium oxide or tantalum oxide. An exemplary encapsulation layer 70 has a thickness of from about 5 to about 50 nanometers (nm), such as about 10 to about 20 nm. The exemplary encapsulation layer 70 is an insulating material with conformal coverage and a thickness sufficient to insulate the MTJ layers 28 in the MTJ structure 12 as described below.

In an exemplary embodiment, the encapsulation layer 70 is titanium oxide and is formed by alternating deposition of layers of titanium by a physical vapor deposition (PVD) process and oxidation of the layers of titanium to form titanium oxide layers. The successive physical vapor deposition and oxidation of titanium layers may include depositing from about 10 to about 40 layers of titanium by a PVD process. In an exemplary embodiment, each layer is oxidized before the next overlying titanium layer is deposited. In an exemplary embodiment, the ex situ oxidation of titanium is performed in a PVD tool with optimized pre-clean and growth conditions. In another embodiment, the encapsulation layer 70 is titanium oxide and is formed by sputtering with a titanium oxide target.

As shown, the encapsulation layer 70 is formed directly on the upper surface 23 of the contact layer 22 and directly on the upper surface 21 of the dielectric layer 20. As a result, the MTJ structure 12 is encapsulated by the encapsulation layer 70, such that the MTJ structure 12 is completely surrounded by the encapsulation layer 70 and the element underlying the MTJ structure 12, i.e., the contact layer 22. Specifically, the encapsulation layer 70 lies continuously from the upper surface 23 of contact 22 directly adjacent sidewall 31, over sidewall 31, top surface 34, and sidewall 32 of the MTJ structure 12, and to the upper surface 23 of contact 22 directly adjacent sidewall 32.

Further, though not illustrated, the encapsulation layer 70 may be deposited over a logic area of the integrated circuit 10 during deposition over the memory area. A single mask may be formed over the memory area so that the encapsulation layer 70 may be removed from the logic area of the integrated circuit 10. The mask may then be removed from the memory area.

After formation of the encapsulation layer 70, the method may continue with the formation of a dielectric material 80 over the encapsulation layer 70. Dielectric material 80 may be formed from a plurality of dielectric layers, including an interlayer dielectric, such as a low k interlayer dielectric. Further, dielectric material 80 may include dielectric layers formed during previous processing. Dielectric material 80 may be blanket deposited over the encapsulation layer 70. As shown, the dielectric material 80 may be planarized, such as by CMP.

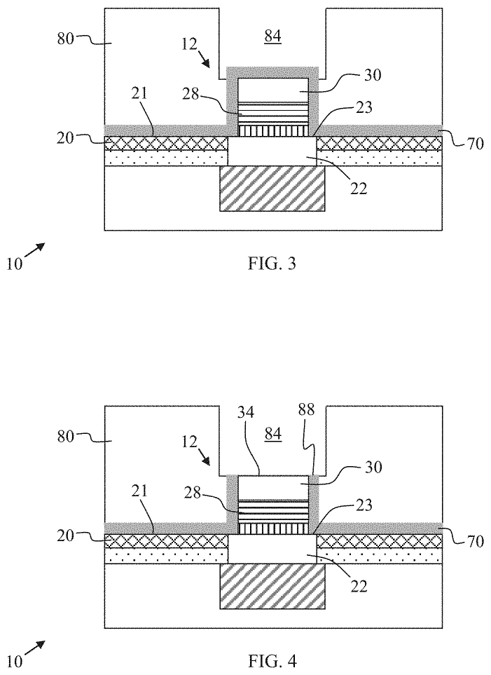

The process may continue in FIGS. 3-5 with processing for removing the encapsulation layer 70 directly overlying the top surface 34 of the MTJ structure 12 for the purpose of electrically connecting the top electrode layer 30 of the MTJ structure 12 to other components in the integrated circuit 10 through additional metallization layers.

In FIG. 3, a trench 84 is formed in the dielectric material 80. For example, a mask may be located and pattered over the dielectric material 80 to form an opening overlying the MTJ structure 12. Then, an etch process is performed to etch the dielectric material 80 directly underlying the opening. An exemplary etch process is anisotropic, such as a reactive ion etch. The exemplary etch process is selective to etching the dielectric material 80 and does not etch, or etches very slowly, the encapsulation layer 70. As a result, each trench 84 is intended to land on the encapsulation layer 70 and expose a portion of the encapsulation layer 70.

In FIG. 4, another etch process is performed to remove the portion of the encapsulation layer 70 exposed by trench 84, thereby enlarging trench 84. For example, the encapsulation layer 70 may be etched using an anisotropic etching process, such as reactive ion etching, selective to etching the encapsulation layer 70. In an exemplary embodiment, the horizontal portion of the encapsulation layer 70 is completely removed. Further, the vertical portions of the encapsulation layer 70 may be partially etched. As a result, the encapsulation layer 70 is formed with upper surfaces 88. While in FIG. 4, the upper surfaces 88 of the encapsulation layer 70 are substantially parallel with the top surface 34 of the MTJ structure 12, the upper portions of the encapsulation layer 70 adjacent the sidewalls 31 and 32 of the MTJ structure 12 may be partially etched. In either case, in an exemplary embodiment, the encapsulation layer 70 remains completely encapsulating the MTJ layers 28 underlying the top electrode layer 30. In other words, a portion of the encapsulation layer 70 on the sidewalls 31 and 32 formed by the top electrode layer 30 may be etched, but the encapsulation layer 70 remains on the sidewalls 31 and 32 of a lower portion of the top electrode layer 30 such that the MTJ layers 28 are distanced from the upper surfaces 88 of the encapsulation layer 70 (and the enlarged trench 84) by a selected minimum distance, such as by about 5 to about 10 nm, to have sufficient process margin to prevent shorting. Thus, the MTJ layers 28 of the MTJ structure 12 are completely surrounded by the top electrode layer 30, the titanium oxide encapsulation layer 70, and the bottom electrode layer 26. As shown, the encapsulation layer 70 directly contacts the top surface 34 and sidewalls 31 and 32 of the MTJ structure 12, the upper surface 23 of the conductive contact 22, and the upper surface 21 of the dielectric layer 20.

Though not shown, the trench formation and encapsulation layer 70 etch process may be performed to remove portions of the encapsulation layer 70 overlying the dielectric layer 20 laterally distanced from the MTJ structure 12.

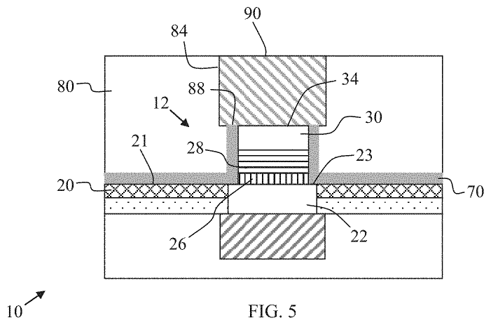

In FIG. 5, conductive material is deposited over the dielectric material 80, in the trench 84, on the top surface 34 of the top electrode layer 30, and on the upper surfaces 88 of the encapsulation layer 70. An overburden portion of the conductive material may be removed from over the dielectric material 80. As a result, a conductive via 90 is formed in the trench 84 and in electrical contact with the top electrode layer 30 of the MTJ structure 12. An exemplary conductive via 90 is formed from conductive material of any type commonly used in the fabrication of via structures, including but not limited to copper-containing materials. In an exemplary embodiment, the conductive material is deposited by an electroplating process. The conductive via 90 may be electrically connected to an overlying metallization layer as is common in semiconductor processing.

As shown in FIG. 5, the conductive via 90 is separated from the MTJ layers 28 by the top electrode layer 30 and the encapsulation layer 70. If trench 84 is formed too deeply by over-etching dielectric material 80, the encapsulation layer 70 still prevents contact between the MTJ layers 28 and the trench 84 and later-formed conductive via 90.

As described herein, integrated circuits with magnetic tunnel junction structures and methods for fabricating integrated circuits with magnetic tunnel junction structures are provided. The integrated circuits and methods described herein provide enhanced protection of MTJ layers 28 in the MTJ structure 12 by encapsulation with a metal oxide encapsulation layer 70 that withstand later processing, such as later etching and annealing processes. As a result, the MTJ structure 12 in the fabricated integrated circuit 10 may exhibit improved performance. As described, the exemplary integrated circuits and methods achieve improved processing flexibility by expanding etching and annealing process parameters.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration as claimed in any way. Rather, the foregoing detailed description will provide those skilled in the art with a convenient road map for implementing the exemplary embodiment or exemplary embodiments. It should be understood that various changes can be made in the function and arrangement of elements without departing from the scope herein as set forth in the appended claims and the legal equivalents thereof

The invention claimed is:

1. A method comprising:
forming a passivation layer;
forming a dielectric layer over the passivation layer, wherein the dielectric layer has an uppermost surface;
forming a trench in the dielectric layer and the passivation layer;
forming a conductive contact layer in the trench, wherein the conductive contact layer has an uppermost surface with a central portion and outer portions;
forming a magnetic tunnel junction (MTJ) structure on the central portion of the conductive contact layer, wherein the MTJ structure has a first sidewall, a second sidewall, and a top surface extending from the first sidewall to the second sidewall;
conformally depositing a titanium oxide encapsulation layer around on the first sidewall, the second sidewall, and the top surface of the MTJ structure, on the uppermost surface of the conductive contact layer, and on the uppermost surface of the dielectric layer, wherein the titanium oxide encapsulation layer includes a bottom surface that is coplanar with the uppermost surface of the conductive contact layer, and the bottom surface of the titanium oxide encapsulation layer directly contacts the outer portions of the uppermost surface of the conductive contact layer;
depositing a dielectric material over the MTJ structure;
etching the dielectric material to form a trench exposing the metal oxide encapsulation layer on the top surface of the MTJ structure;
removing all of titanium oxide encapsulation layer from the top surface of the MTJ structure to expose the top surface of the MTJ structure; and
after removing all of the titanium oxide encapsulation layer from the top surface of the MTJ structure to expose the top surface of MTJ structure, forming a conductive via in the trench that is in direct contact with the top surface of the MTJ structure.

2. (canceled)

3. The method of claim 1 wherein the titanium oxide encapsulation layer is conformally deposited using a physical vapor deposition (PVD) process.

4. The method of claim 1 wherein conformally depositing the titanium oxide encapsulation layer on the first sidewall, the second sidewall, and the top surface of the MTJ structure comprises:
alternating depositing layers of titanium by a physical vapor deposition (PVD) process and oxidizing the layers of titanium to form titanium oxide layers.

5. The method of claim 1 wherein conformally depositing the titanium oxide encapsulation layer on the first sidewall, the second sidewall, and the top surface of the MTJ structure comprises:
sputtering titanium oxide.

6. The method of claim 1 wherein the titanium oxide encapsulation layer has a thickness of about 5 nm to about 50 nm.

7-17. (canceled)

18. A structure comprising:
a passivation layer;
a dielectric layer on the passivation layer, the dielectric layer having an uppermost surface;
a conductive contact layer located in an opening in the dielectric layer and the passivation layer, the conductive contact layer having an uppermost surface including a central portion and outer portions;
a magnetic tunnel junction (MTJ) structure overlying the central portion of the conductive contact layer, the MTJ structure having a first sidewall, a second sidewall, and a top surface extending from the first sidewall to the second sidewall;
a conductive via over and in direct contact with the central portion of the MTJ structure; and
a titanium oxide encapsulation layer on the first sidewall, the second sidewall, and the top surface of the MTJ structure, on the outer portions of the uppermost surface of the conductive contact layer, and on the uppermost surface of the dielectric layer.

19. The structure of claim 18 wherein the MTJ structure includes a top electrode layer, MTJ layers, and a bottom electrode layer, and the MTJ layers are completely surrounded and directly contacted by the top electrode, the titanium oxide encapsulation layer, and the bottom electrode layer.

20. The structure of claim 18, wherein:
the dielectric layer has an uppermost surface coplanar with the uppermost surface of the conductive contact layer;
the MTJ structure has opposite sidewalls; and
the titanium oxide encapsulation layer directly contacts the sidewalls of the MTJ structure and the uppermost surface of the dielectric layer.

21. The structure of claim 18 wherein the passivation layer is comprised of a silicon carbide-based passivation material including nitrogen.

22. The structure of claim 18 wherein the uppermost surface of the conductive contact layer is coplanar with the dielectric layer.

23. The structure of claim 18 wherein the titanium oxide encapsulation layer has a thickness of about 5 nm to about 50 nm.

24. The structure of claim 18 wherein the titanium oxide encapsulation layer has a thickness of about 10 nm to about 20 nm.

25. A structure comprising:
a dielectric layer;
a conductive contact layer located in an opening in the dielectric layer, the conductive contact layer having an uppermost surface including a central portion and outer portions;
a magnetic tunnel junction (MTJ) structure overlying the central portion of the conductive contact layer, the MTJ structure having a first sidewall, a second sidewall, and a top surface extending from the first sidewall to the second sidewall;
a conductive via over and in direct contact with the central portion of the MTJ structure; and
a titanium oxide encapsulation layer on the first sidewall, the second sidewall, and the top surface of the MTJ structure, on the outer portions of the uppermost surface of the conductive contact layer, and on the uppermost surface of the dielectric layer, the titanium oxide encapsulation layer including a bottom surface that is coplanar with the uppermost surface of the conductive contact layer, and the bottom surface of the titanium oxide encapsulation layer directly contacting the outer portions of the uppermost surface of the conductive contact layer.

26. The structure of claim 25 wherein the dielectric layer has an uppermost surface, and the uppermost surface of the conductive contact layer is coplanar with the uppermost surface of the dielectric layer.

27. The structure of claim 25 wherein the titanium oxide encapsulation layer has a thickness of about 5 nm to about 50 nm.

28. The structure of claim 25 wherein the titanium oxide encapsulation layer has a thickness of about 10 nm to about 20 nm.
